(19) United States
(12) Patent Application Publication
(10) Pub. No.: US 2019/0097083 A1
(43) Pub. Date: Mar. 28, 2019

(54) INDIRECT BAND GAP LIGHT EMITTING DEVICE

(71) Applicant: INSIAVA (PTY) LTD., Pretoria, Gauteng (ZA)

(72) Inventors: Petrus Johannes VENTER, Pretoria (ZA); Marius Eugene GOOSEN, Centurion (ZA); Christo JANSE VAN RENSBURG, Pretoria (ZA); Nicolaas Mattheus FAURÉ, Pretoria (ZA)

(73) Assignee: INSIAVA (PTY) LTD., Pretoria, Gauteng (ZA)

(21) Appl. No.: 16/083,094

(22) PCT Filed: Mar. 8, 2017
(86) PCT No.: PCT/IB2017/051352

§ 371 Date: Sep. 7, 2018

(30) Foreign Application Priority Data
Mar. 8, 2016 (ZA) 2016/01593

(51) Int. Cl. H01L 33/18; H01L 27/15; H01L 33/00; H01L 33/28

(52) U.S. Cl. CPC H01L 33/18; H01L 33/28; H01L 33/0058; H01L 27/153

(57) ABSTRACT

An indirect band gap light emitting device comprises a first body of non-monocrystalline indirect band gap semiconductor material. In this first body, two regions are formed: a first region with a first doping kind and a first doping concentration and a second region with a second doping kind and a second doping concentration. A junction is formed between the first region and the second region with a terminal arrangement connected to the first body and arranged to reverse bias the junction so as to emit light. The first body is formed from a deposited layer of semiconductor to form an integral part of a substrate. An integrated circuit can include the light emitting device and a second body of monocrystalline indirect band gap semiconductor material. A third body may separate and galvanically isolate the first and second bodies from each other.

### FIELD OF DISCLOSURE

This disclosure relates in general to optoelectronic devices and more particularly to a light emitting device fabricated from an indirect band gap semiconductor material.

### BACKGROUND OF DISCLOSURE

### Silicon Light Emission

Silicon is the prevailing material of choice for creating electronic integrated circuits (ICs) found in practically all modern electronic devices. The dominant fabrication technology for fabrication of ICs is CMOS (complementary metal-oxide semiconductor) that makes use of silicon's ability to grow exceptionally high quality thermal oxide used as gate insulator to create transistor devices of both polarities on a single chip.

Although well-suited for integrated electronics, silicon is a poor optical emitter due to its indirect band gap material properties. Notwithstanding this fact, the possibility of a silicon light emitter may be extremely useful. This has been a topic of numerous publications, both academic and commercial, as well as a number of patented disclosures. A light emitter forming part of an integrated circuit can be of great commercial value in various applications.

Light emission from semiconductor materials is generally created either 1) by forward biasing a pn-junction, or 2) by reverse biasing a pn-junction to the point of breakdown, usually through avalanche or Zener mechanisms or a combination of both, resulting in a phenomenon called hot carrier electroluminescence. In the forward biased case, light emission results from the recombination of diffused minority carriers with the emission spectrum centered around the material's band gap energy. In GaAs or other direct band gap materials, this process is relatively fast and efficient. In indirect band gap materials, such as silicon and germanium, this is a very slow and inefficient process. When reverse biasing a junction towards breakdown, hot carrier electroluminescence occurs as a result of several types of interaction between highly energetic (hot) carriers being activated by a large electric field, resulting in wide spectrum light emission ranging from approximately 300 nm to approximately 1000 nm. Unlike phonon-assisted electron-hole recombination, compared to the forward biased case for indirect band gap materials, this process is almost always very fast.

In order to integrate these light emitting devices into an integrated circuit, or microchip, it is necessary to create and configure pn-junctions in the active semiconductor material using a similar approach to that used to create transistors and other active semiconductor devices. Active devices usually refer to devices employing pn-junctions configured to perform a specific function or activity based on its semiconducting properties. When monolithically integrated on chip, these device structures are formed close to and against the surface of the monocrystalline (that is, long-range homogenous crystalline framework) body of a single crystal semiconductor material. This surface region is commonly called the active layer or device layer, that is, the monocrystalline layer in which these active devices reside. A high quality single crystal material (or monocrystalline material) is preferred for active devices due to the increased electron and hole mobility, parameters that determine device performance. n- and p-regions are formed by ion implantation, gas diffusion or any process capable of introducing dopant impurities into the single crystal body. Subsequently, devices formed in the active layer are completed by forming additional layers that are grown or deposited on top of the device layer, and may comprise, amongst others, thermally grown oxide layers, deposited transistor gate layers, deposited insulating material layers, metal layers and “via” structures (structures reaching vertically through the insulating layers to establish electrical contact between different layers) to enable electrical access to the electronic devices formed on-chip.

Based on the differences introduced by the so-called starting layer, the active layer can be categorized as either of the following:

1. The active layer can refer to a stratum close to the surface of a body of single crystal semiconductor material, in which the remainder of the body does not take part in the behavior of devices embedded in the active layer. The remainder of the body is commonly referred to as the bulk, or substrate. This is typically encountered in, and referred to as, standard bulk CMOS fabrication processes where the starting material is a piece of single crystal silicon wafer.

2. The active layer can refer to a monocrystalline layer on top of an insulating material, separated from the bulk by this insulating layer. An example of such a processing technology is silicon on insulator (SOI), a manufacturing technology that comprises a thin primary layer of monocrystalline semiconductor material in which devices are formed that are electrically insulated from the monocrystalline bulk material (in this case acting as the handle for mechanical stability). These functions are determined by the starting wafer. During fabrication, devices are formed by doping n- and p-regions, while vertical etching and subsequent oxide deposition allow semiconductor “islands” to be created, providing superior electrical performance under certain conditions. Although the handle is usually electrically inactive, prior art exists in which the single crystal bulk or handle could be utilized as a secondary active body (U.S. Pat. No. 6,838,301). This is uncommon in commercial SOI fabrication processes.

### Current Examples in Prior Disclosures

Light emitting devices that are formed using standard processing technologies face numerous design and performance challenges. One such challenge lies in the extraction efficiency of the light. In a standard commercial CMOS process, a pn-junction formed as an integral part of the bulk silicon body generates light isotropically (that is, in all directions, evenly). As a function of the surface geometry, at least half of the generated light is reflected back at the surface of the body and reabsorbed by the bulk material itself. This can partially be alleviated, or improved on, in at least two ways:

1. Modification of the surface of the device layer in bulk CMOS can improve the extraction efficiency. In U.S. Pat. No. 9,117,970, the geometry at the surface of the device layer is altered to create more favorable light emission from a standard bulk CMOS wafer.

2. Light can be reflected from the bulk by creating light sources in the device layer of an SOI CMOS process in such a way that the thin layer of monocrystalline material is separated from the bulk material by an isolating layer (this buried layer is usually formed with silicon dioxide, SiO₂). The differing refractive index of the materials creates an additional interface from which light is reflected away from the bulk, improving the extraction probability and efficiency. For example, U.S. Pat. No. 8,669,564 discloses a light emitting device of single crystal semiconductor material on an SOI CMOS where the light emitting device is embedded in the active or device layer, thereby improving extraction efficiency. SOI CMOS wafers are approximately three times more expensive than equivalent standard bulk CMOS wafers.

Another benefit that SOI CMOS enjoys over its bulk counterpart is its ability to make limited use of the handle material to create simple circuit structures in addition to the usual transistor devices in the device layer. U.S. Pat. No. 6,838,301 discloses an active pixel design in an SOI technology whereby the secondary monocrystalline body or handle (the primary being the device layer) is doped to form a detecting element. The thin primary layer of monocrystalline material is subsequently used to implement the support circuitry. The disclosure of U.S. Pat. No. 6,838,301 shows the benefit of smaller geometries and smaller integration associated with using two active layers on the same integrated circuit.

SOI CMOS therefore holds a distinct advantage over bulk CMOS due to the fact that the device layer is separated from the bulk or handle body of semiconductor material.

### Object of the Disclosure

Accordingly, it is an object of the present disclosure to establish a light emitting device, in a non-monocrystalline layer of indirect band gap semiconductor material, integrally formed on top of and as part of the same substrate, which the Applicant believes brings the advantages and improved performance of an SOI CMOS device to standard bulk CMOS processing technologies. The non-monocrystalline layer of indirect band gap semiconductor material can be galvanically isolated from any layer of monocrystalline indirect band gap semiconductor material by an isolation material. The Applicant further believe that through the combination of using a non-monocrystalline material to implement a light emitting junction and an electrically separated monocrystalline layer used to implement other devices, such as a detecting element, numerous applications result, one of which is galvanic isolation in opto-isolators.

### SUMMARY OF DISCLOSURE

The disclosure is summarized in the claims. Similar or additional aspects of the disclosure may be repeated hereunder.

Accordingly, the disclosure provides an indirect band gap light emitting device comprising:
a first body of non-monocrystalline indirect band gap semiconductor material;
at least one junction formed between a first region of the first body with a first doping kind and a first doping concentration and a second region of the first body with a second doping kind and a second doping concentration; and
a terminal arrangement connected to the first body and arranged to reverse bias a junction formed between the first and second regions so as to emit light,
whereby the light emitting device is formed integrally as part of a single substrate and whereby the light emitting device is formed in a deposited layer of semiconductor to form an integral part of the substrate.

The first doping kind may be different from the second doping kind. The first doping concentration may be different from the second doping concentration.

State of the art technology relies on creating light sources by forming pn-junctions in the monocrystalline bodies present in an integrated circuit. Instead of implementing a light source in these monocrystalline device layers, this present disclosure provides for making use of a deposited non-monocrystalline layer of an indirect band gap semiconductor that forms an integral part of an integrated circuit. This layer may be of polycrystalline nature, or may even be completely amorphous. A key difference is that these layers are deposited as part of the fabrication process used to produce integrated circuits, while monocrystalline layers are either pre-formed, or epitaxially grown from an existing crystal seed or monocrystalline structure. The Applicant believes that limiting the creation of light emitting regions to these monocrystalline layers is unnecessary and by breaking this limitation certain distinct advantages are attained.

From applicable experience, the Applicant furthermore has reason to believe that light emission is largely independent of the crystalline structure of the material, and that indirect band gap semiconductor material will emit light irrespective of whether the material has a regular crystal structure that can be characterized as being a single crystal, such as being predominantly monocrystalline, or contains crystallites with grain boundaries, such as being characterised as polycrystalline, or whether the material has no regular crystal structure, such as being amorphous. By depositing layers on a substrate, light emitters can be formed irrespective of the composition of the substrate. The substrate may therefore be of a single material, or may consist of multiple materials.

The non-monocrystalline indirect band gap semiconductor material may be a silicon material.

The first body may be polycrystalline or amorphous in nature. The first body may have characteristics within the continuum that spans from amorphous through polycrystalline up to, but not including, monocrystalline characteristics, taking cognisance of the fact that the material may have features such as impurities, defects or other localised crystal characteristics that deviate from the crystal's overall characteristic structure. These deviations may include, but are not limited to, dislocations in a monocrystalline lattice, or a localised regular crystal lattice (crystallite) existing between grain boundaries in a material that has a polycrystalline structure, such as polysilicon.

An integrated circuit containing the light emitting device may include a second body of monocrystalline indirect band gap semiconductor material. The first and second bodies may be separated by a third body. The second body may be integrally part of the substrate on which the non-monocrystalline layer, the layer from which the first body is formed, is deposited, or it may be separate from the substrate. The third body may be configured to galvanically isolate the first and second bodies from each other.

An example of a deposited layer, that may be used to form the first body when creating a light emitter, is the non-monocrystalline layer generally used to create the well-known transistor gate. This deposited layer, or gate material, is present in the majority of modern CMOS processes. It may be a polysilicon layer (not monocrystalline) that is deposited on top of the device layer after a thin thermal oxide is grown to isolate the gate from the underlying transistor. Polysilicon is usually gradually formed or “grown” through vapor deposition of silane gas (SiH₄) in a chemical process, usually through LPCVD (low pressure chemical vapor deposition). However, the layer's resultant crystal structure may be disorganized, not monocrystalline. Formation of crystallites may occur during processing, resulting in the material's polycrystalline structure.

This polysilicon layer may be used not only as a transistor gate. Similar to transistor gates, there may multiple instances of the first body, formed from the same polysilicon layer, distributed transversally over the monocrystalline second body. Additionally, there may be multiple polysilicon layers, e.g., plural instances of the first body formed in the different layers (in a vertical fashion as opposed to transversally), deposited during fabrication of an integrated circuit, each with a different purpose and separated by electrically non-conductive insulating layers, e.g., the third body, such as silicon dioxide or silicon nitride. These other polysilicon layers are often used to create resistors, capacitors and other passive circuit elements. The process of depositing a layer as part of a single fabrication process is distinctly different from that of taking a separate, prior formed, semiconductor or light source and joining it to the first IC. In addition, the deposited material is not necessarily restricted to silicon;

germane (GeH₄) may be introduced together with silane to form a hybrid germanium and silicon material, both materials having an indirect band gap. Any other semiconductor, both of direct or indirect band gap nature, that is capable of being deposited may be used to form such a deposited layer having a non-monocrystalline crystal arrangement.

The third body may consist of a plurality of layers comprised of a group of, but not limited to, inter-metal isolating layers, metal layers or other semiconducting materials. The third body may contain at least one layer with an electrically non-conductive, or insulating, region between the first and second bodies. The non-conductive isolating layer may comprise any non-conducting layer, including at least one of thermally grown SiO₂, deposited SiO₂, Si₃N₄, other polymer layers (such as polycarbonate), vacuum, gases including ambient gases, air, noble or inert gas, or any other material with electrically insulating properties.

A photosensitive region may be formed in the second body. The photosensitive region may be configured to operate as a light detecting element. The light detecting element may be positioned to capture light generated in the first body and traversing through the third body.

The light emitting device may include an auxiliary body, or plural auxiliary bodies, of a non-monocrystalline indirect band gap semiconductor material that is distinct from the first and second bodies. The auxiliary body may be separated from the first and second bodies by the third body and that is deposited to form an integral part of the substrate. A photosensitive region may be formed in the auxiliary body.

The first body may be encapsulated by the third body, except for the terminal arrangement used to reverse bias the junction formed in the first body.

The first body may be formed on top of the third isolating body without being fully enclosed, thereby resulting in a partial bordering by the first body of the third body.

Metal layers as well as the terminal arrangement may be configured to reflect and direct the light generated in the first body towards the photosensitive areas on the second body, or a photosensitive area on any other body, and to reduce optical propagation of light in a direction opposite the second, or additional bodies comprising photosensitive regions.

By forming pn-junctions of different configurations (for example pn, pnp, npn, p⁺n, n⁺p, p⁺nn⁺, p⁺p⁺, p⁺-i-n⁺, p-i-n, and other combinations thereof) in these deposited semiconductor layers from which the first body is formed and by selective etching of the deposited layer to form the first body, it may be possible to create deposited light sources on top of, but separated from, the device layer present in the second body. By separating the light source, e.g., the first body, and device layer, e.g., the second body, by other layers, e.g., the third body, some of which are electrically non-conductive, this approach may effectively create an isolated or a “floating” light source that is in proximity but not part of the device layer and that may effectively be isolated from any other semiconductor body on-chip.

This approach may bring certain attributes of light sources created in SOI CMOS to bulk CMOS in a cost-effective way. The advantages are not limited to bulk CMOS; creating a deposited light source may be possible on SOI CMOS as well, in addition to the already existing monocrystalline device layer that is electrically separate from the handle material. The non-monocrystalline layer may be doped either using the same masks used to dope the underlying device layer, or a different set of masks targeting junction and feature formation specifically to address the configuration of the floating layer, e.g., the first body. The doped regions may be configured in various ways and for a number of purposes.

For example, multi-junction devices may be formed to create pnp. or npn-regions with at least one junction being reverse biased to emit light while the other can be forward biased so that the associated depletion regions “punch through” (U.S. Pat. No. 8,759,845). An example may be a single junction formed in the presence of two highly but oppositely doped regions, such as in a p⁺nn⁺- or p⁺pn⁺-based configuration, in which the regions are appropriately positioned so as to enable the depletion region associated with the junction to “reach through” the lighter doped region in order to extend between the two highly doped regions (US 20120009709).

Because these layers are deposited as part of the standard CMOS fabrication processes, no exotic or incompatible materials are introduced.

Another benefit is that it may be possible to deposit such a layer at an arbitrary stratum, thereby customizing its separated position relative to the monocrystalline device layer on which it resides or in relation to any other deposited layers. In fact, a light source created using a deposited polysilicon layer may reside anywhere in the back end of line (BEOL) stack of a CMOS or SOI CMOS process. The deposited light source may be electrically accessed using the same metal and via interconnect layers already available on chip as part of the fabrication process. These metal interconnect layers and corresponding interlayer dielectric layers may be configured to control the propagation of light emitted from the light source in order to make more efficient use of the emitted light. For example, a reflective metal layer can be added underneath the light source in order to reflect light towards the chip surface, thereby enabling more light to exit the chip surface. Alternatively, a reflective metal layer above the light source can be configured to reflect light down towards the monocrystalline chip substrate, where photosensitive structures may exist, in order for more efficient coupling to these photodetection elements. The light source may be separated by the reflective layer through the formation of an insulating layer, such as deposited silicon dioxide (SiO₂), silicon nitride (Si₃N₄) or polyimide.

Because the present disclosure may allow for the deposited light source to be electrically separated from the underlying device layer and bulk or handle, it may be possible for light emission from a light source formed in the deposited layer to interact with semiconductor devices and circuitry in the device layer or bulk or handle in the absence of an electrical connection between the light source and the underlying semiconductor devices. Where a photosensitive layer is present in the device layer or handle or bulk or other deposited layers, it may be possible to transfer information optically across an electrically insulating barrier, thereby providing galvanic isolation between the light source and the photo-detecting element or photosensitive region.

In addition, because the present disclosure may rely on deposited semiconductor materials, the formation of photosensitive regions may not necessarily be limited to the monocrystalline device layer or bulk or handle materials but can be embedded in any underlying or overlying non-monocrystalline deposited layers in relation to the light source and separated by insulating materials. In fact, through selective etching, a light source may be located adjacent a photosensitive region formed from the same deposited layer, effectively creating opportunity for an IC designer to place detectors above, below and beside the light source. The present disclosure may therefore be well-suited for use in on-chip opto-isolation.

By utilizing two chips co-located in a single package, it may be possible to produce a very cost effective packaged optical isolator, which can provide uni-directional or bi-directional isolated communication. For example, a first IC containing a light emitting structure and a corresponding photosensitive detection region configured for optical communication between this region and the light source may be positioned in proximity (on top of or next) to a second integrated circuit, whereby the second integrated circuit may provide a signal to control the light emitted from the light source on the first chip. This light may be detected by the isolated photosensitive region on the first chip and converted into an electrical signal to be further used by the first IC. In a reciprocal fashion, the first chip may be used to drive a light source present on the second chip that is isolated from a photosensitive region on the second chip in order to communicate optically between such light source and a detection circuitry on the second chip, thereby providing for bi-directional optically isolated communication.

An integrated display may be formed when multiples of the light emitting structures are arranged in an array or matrix where the light emitting structures can be individually addressed. Because of the emission spectrum, a function of the semiconductor material, light emitted from such an array or matrix can be perceived by the human eye to be human readable. It may also be detected by other photosensitive detectors in order to become machine readable. A two-dimensional image or text representation of data can therefore be created by selectively switching individual light emitters on or off in the required way. Moreover, the image or text representations do not need to be static, but may dynamically change in a time dependent manner, depending on the data to be represented on the integrated display. The output can be modulated according to the data it represents, for example, the intensity of light emitted per light emitting element can be varied in brightness, according to the data it is representing, by either changing the continuous current through the light emitting structures, or by making use of time-based modulation, such as pulse width modulation (PWM), on order to establish light of varying intensity. The data that can be represented may either be supplied or originated by a source off-chip, or it may be a representation of the state of the chip itself, or a combination thereof.

Since the light emitting elements do not form part of the monocrystalline active layer, wherein the rest of the integrated electronic structures reside, the benefit lies in that the driving circuitry for each light emitting element can consume a smaller area and may ultimately reside underneath the light emitting elements. The end result produces a smaller pixel pitch than previously possible.

### BRIEF DESCRIPTION OF DRAWINGS

The disclosure will now be further described, by way of example, with reference to the accompanying diagrammatic drawings.

In the drawings:

FIG. 1 is a cross-sectional view of a first embodiment of the light emitting device fabricated in a non-monocrystalline indirect band gap semiconductor material;

FIG. 2 is a section on line II in FIG. 1;

FIG. 3 is a section on line III in FIG. 1;

FIG. 4 is a cross section of a second embodiment of the present disclosure, with a partially encapsulated body of non-monocrystalline semiconductor material;

FIG. 5 is a schematic view of a third embodiment of the disclosure and shows a circuit level representation of the light emitting device interacting with a photosensitive region, such as a detector, situated in close proximity on and formed as integral part of the same integrated circuit die substrate.

FIG. 6 is a cross section of a fourth embodiment where a light detecting element is configured in the second body of monocrystalline material, spatially configured to capture the light emanating from the first body of non-monocrystalline material;

FIG. 7 shows a cross section of the fifth embodiment where a light detecting element is configured in at least one additional layer of non-monocrystalline material, spatially configured to capture light emanating from the first body of non-monocrystalline material; and

FIG. 8 shows a cross section of a sixth embodiment where a light emitting element is spatially configured in relation to a metal layer, in order to guide and reflect the light emitted from the light emitter towards the upper surface of the single substrate.

### DETAILED DESCRIPTION OF EXAMPLE EMBODIMENT

The following description of the disclosure is provided as an enabling teaching of the disclosure. Those skilled in the relevant art will recognize that many changes can be made to the embodiment described, while still attaining the beneficial results of the present disclosure. It will also be apparent that some of the desired benefits of the present disclosure can be attained by selecting some of the features of the present disclosure without utilizing other features. Accordingly, those skilled in the art will recognize that modifications and adaptations to the present disclosure are possible and can even be desirable in certain circumstances, and are a part of the present disclosure. Thus, the following description is provided as illustrative of the principles of the present disclosure and not a limitation thereof.

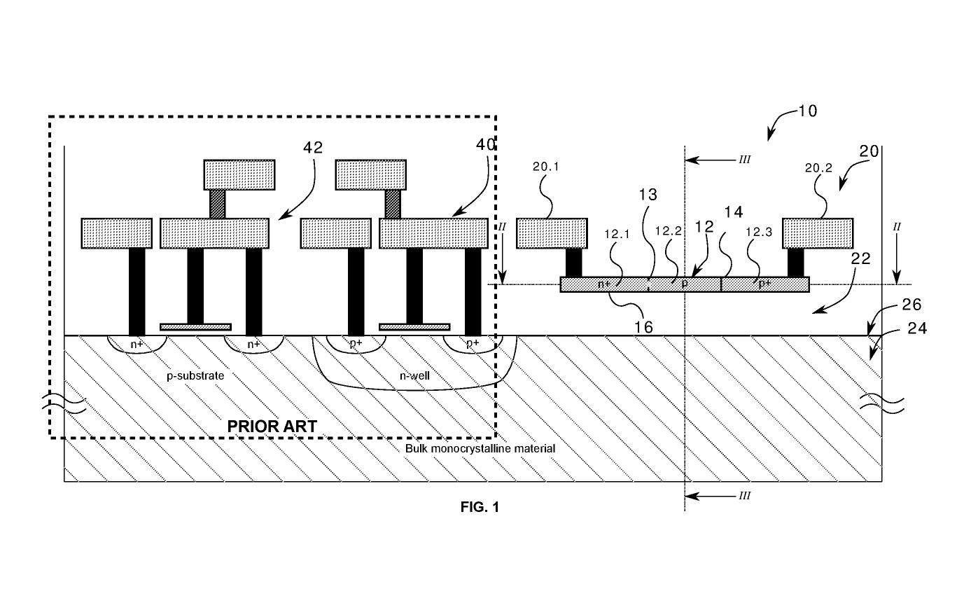

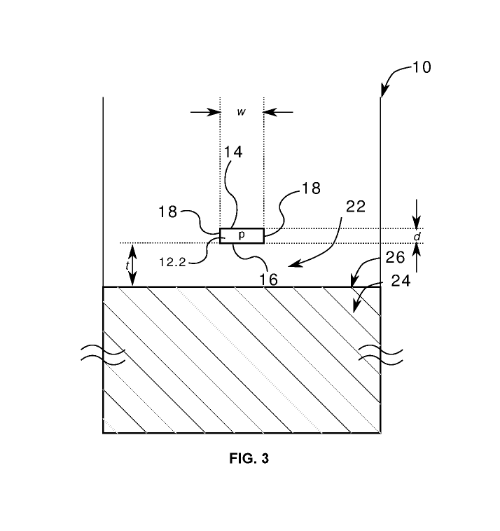

A light emitting device, in accordance with the disclosure, is fabricated from an indirect band gap material and is generally designated by reference numeral 10 in FIGS. 1-3. For context, the light emitting device 10 is illustrated in relation to a PRIOR ART PMOS transistor 40, and a PRIOR ART NMOS transistor 42, as implemented in a standard CMOS process. The PRIOR ART transistors 40, 42 are implemented in the bulk body monocrystalline material 24. The light emitting device 10 comprises a first body (collectively referred to by numeral 12 and comprising regions 12.1-12.3) of an indirect band gap semiconductor material having a non-monocrystalline crystal arrangement.

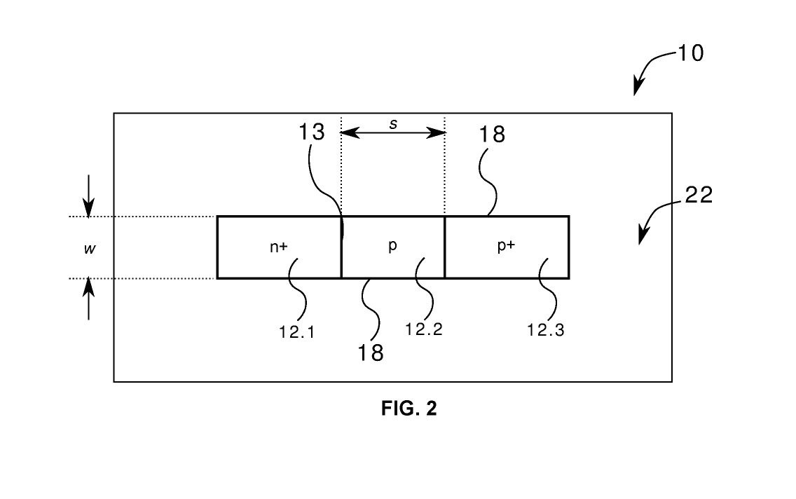

The first body 12 is illustrated in FIGS. 1-3 as rectangular; however, it will be appreciated that it may be any practicable shape in a transverse direction, such as circular or square. In the embodiments illustrated in FIGS. 1-3, the first body 12 is rectangular in shape and shown to have a thickness d and width w with a top wall 14, bottom wall 16, and sidewalls 18 (as shown in FIG. 2). The light emitting device 10 comprises a second body of monocrystalline semiconductor material 24. A body analogous to the second body 24 is typically used as the electrically active material when implementing PRIOR ART transistors 40 and 42.

In the present disclosure, the first body 12 and the second body 24 are electrically insulated from each other by a third body 22 comprising an isolation material. The bottom wall 16 of the first body 12 and an interface 26 formed between the second and third bodies 24, 22 are separated with an isolation distance, t. FIGS. 1-3 show that the first body 12 may be fully encapsulated by the third body 22 except for terminal contacts 20.1, 20.2.

The first body 12 comprises a first region 12.1 of first doping kind and first doping concentration. It further comprises a second region 12.2 of second doping kind and second doping concentration. A junction 13 is formed between first and second regions 12.1, 12.2. The first body 12 may further comprise a third region 12.3 of second doping kind and third doping concentration. The third region 12.3 is positioned such that the second region 12.2 is sandwiched between first region 12.1 and the third region 12.3 with a spacing, s.

The first doping kind may be n-type while the second and third doping kinds may then be of opposite p-type. The first and third doping concentrations may be higher than the second doping concentration. In other embodiments, reversed doping kinds may be used.

The junction 13 can be reverse biased by means of a terminal arrangement, generally designated reference numeral 20. Suitable electrical contacts 20.1, 20.2 of the terminal arrangement 20 are connected to the first region 12.1 and third region 12.3 respectively. When in use, the junction 13 is reverse biased to emit light. Light is emitted, exiting the device mainly through the walls 14, 16, 18 of the first body 12.

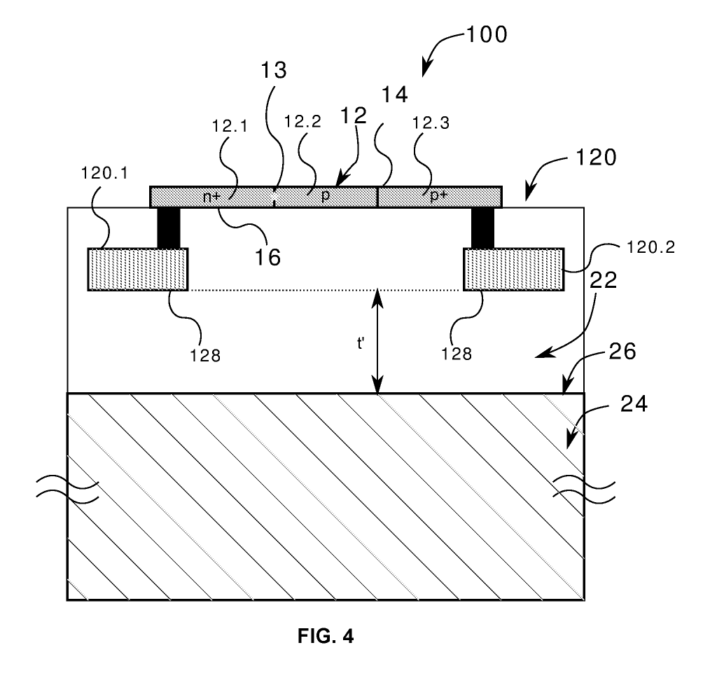

In a second embodiment of the present disclosure, as shown in FIG. 4, the first body 12 may only be partially surrounded by the third body 22. In this embodiment, the first body 12 is formed on top of the third body 22 in contrast with the first embodiment where the first body 12 is formed inside the third body 22. In this embodiment, the third body 22 provides a galvanic isolation distance, denoted t′, between the bottom wall of the first body 16, or the bottom wall of the terminal arrangement 128, and the interface 26 between the second and third bodies 24, 22, whichever is the least. To this end, the third body 22 providing the isolation may consist of a plurality of layers of which at least one layer should consist of an isolating material. The effective isolation distance t′ will then be determined by the lowest electrically conducting layer.

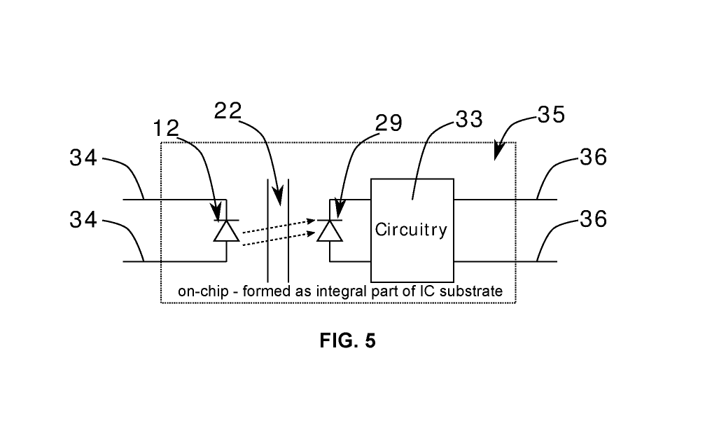

In a third embodiment of the disclosure (FIG. 5), a photosensitive region 29 is located in proximity to the first body 12 containing the at least one junction 13 while being isolated by the isolation material and third body 22. The non-monocrystalline first body 12 emits light to be detected by the photosensitive region 29 acting as a photodetector. Supporting circuitry 33 is located in proximity and electrically connected to the photosensitive region 29 while remaining galvanically isolated from the first body 12 by the third body 22. This circuitry may include, but is not limited to, amplifiers, analogue to digital converters, digital circuits, and the like.

Both the light emitting first body 12 and the photosensitive region 29 are integrally part of the same semiconductor die substrate 35. Input connections 34 provide the physical and electrical connection to the first light emitting body 12. Output connections 36 provide physical and electrical connection to the photosensitive region 29 and supporting circuitry 33.

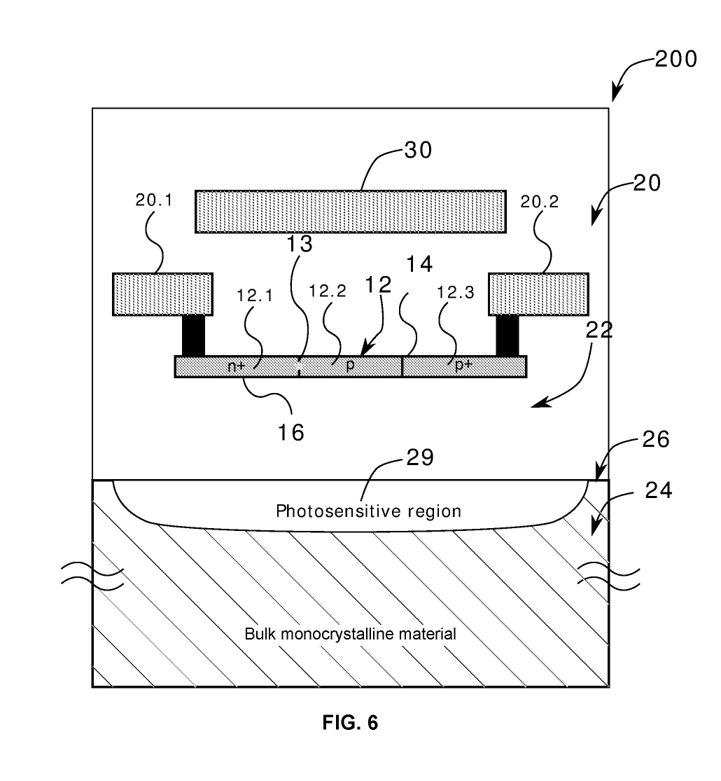

In a fourth embodiment of the present disclosure (FIG. 6), the light emitting device 200 comprises a photosensitive region that is usually doped, formed in the second body 24, and configured as a light detecting element 29 (electrical contacts not shown). The light detecting element 29 is configured and positioned in close proximity to the first body to capture the light emanating from the first body, 12. The third body 22 maintains electrical isolation between the first body 12 and the light detecting element 29 configured in the second body 24. Additionally, metal layers 30 present in standard processes as well as the provided terminal arrangement 20 may be configured to reflect and guide the generated light downward to be detected by the light detecting element 29 thereby increasing the amount of light reaching the detecting element 29. Metal layers configured on the same substrate are typically separated via inter-metal dielectric layers, or connected using inter-metal connection structures (commonly referred to as vias). The metals used as inter-metal connection structures or simply vias may also be utilized to guide and reflect the light in the appropriate direction, similar to metal layer 30.

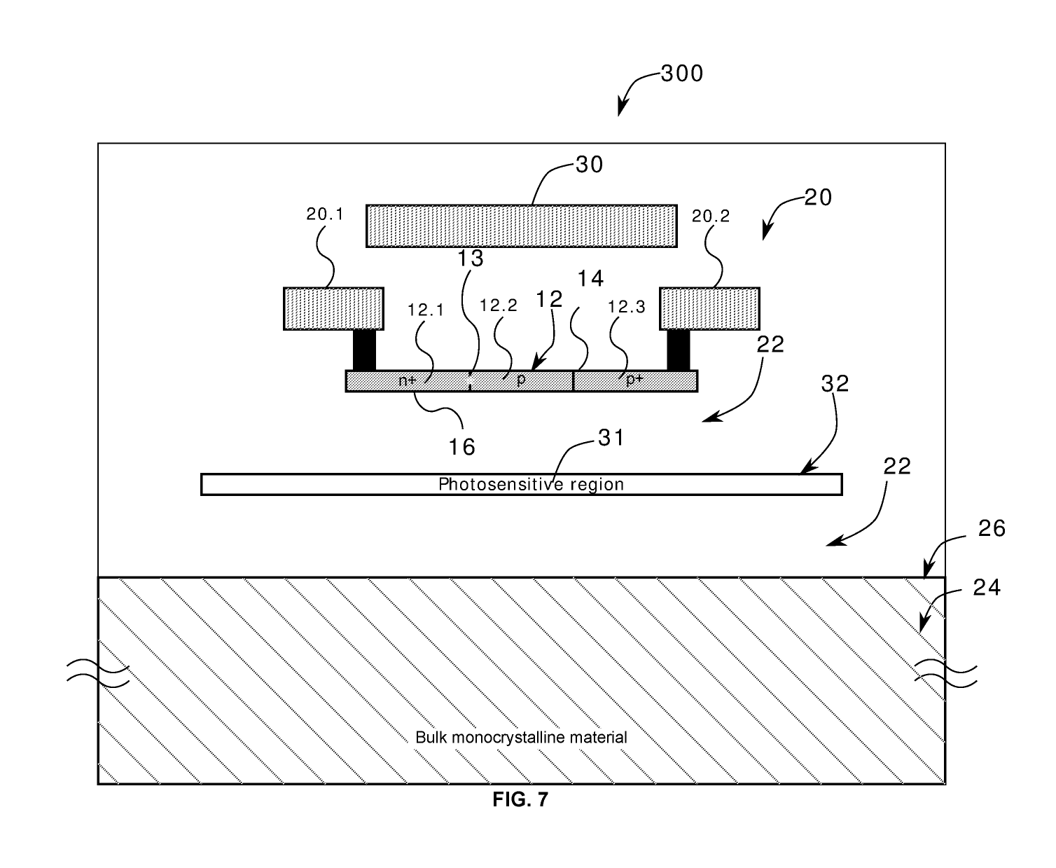

In a fifth embodiment of the present disclosure (FIG. 7), the light emitting device 300 comprises a photosensitive region 31 formed in at least one auxiliary or additional body 32 of non-monocrystalline semiconductor material that is distinct from other semiconductor bodies, configured in proximity of the first body 12 and separated from the first and second bodies 12, 24 by the third body 22. The photosensitive region 31 is formed in the deposited and doped auxiliary body 32 to form an integral part of the same substrate, and configured to operate as a light detecting element (electrical contacts not shown). Metal layers, integrally part of the same substrate 30, as well as the terminal arrangement 20 may be configured to guide and direct light towards the photosensitive region 31. Metal layers configured on the same substrate are typically separated via inter-metal dielectric layers, or connected using inter-metal connection structures or vias. The metals used as inter-metal connection structures or simply vias may also be utilized to guide and reflect the light in the appropriate direction, similar to metal layer 30.

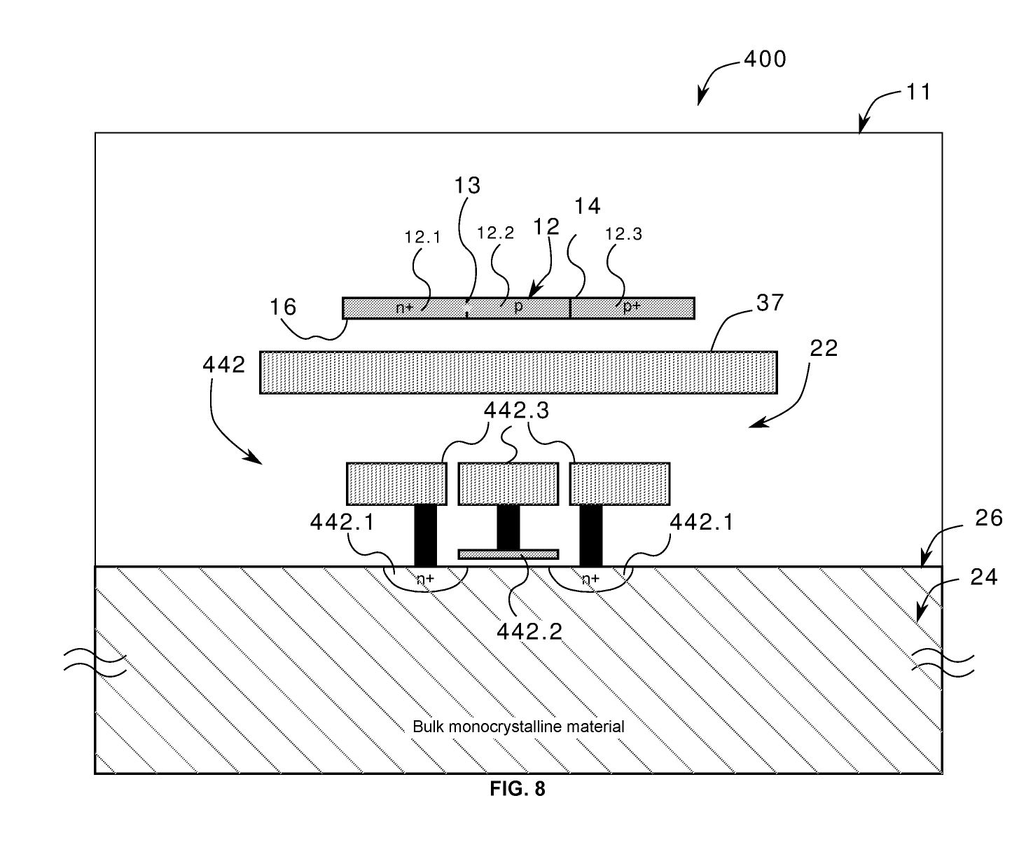

In a sixth embodiment of the present disclosure (FIG. 8), the light emitting device 400 comprises a metal layer 37 formed underneath the non-monocrystalline body 12 containing the light emitting junction 13 formed at the interface of the first region 12.1 and the second region 12.2. The metal layer 37 is used to direct and reflect light emitted through the bottom surface 16 of the first body 12 towards the top surface 11 of the substrate. The terminal arrangement used to connect to the first body 12 is not shown.

Additionally, an NMOS transistor 442 with doped regions 442.1, a non-monocrystalline gate material 442.2, and a metal transistor terminal arrangement 442.3 may be formed underneath metal layer, 37, and underneath the first body, 12. In the absence of the metal layer 37, the metal transistor terminal arrangement 442.3 may also perform the function of light guiding and reflecting layer for directing the light towards the top surface 11 of the substrate. The transistor may instead be a PMOS transistor 40 (FIG. 1) with similar well defined entities.

1-46. (canceled)

47. An indirect band gap light emitting device comprising:
a first body of non-monocrystalline indirect band gap semiconductor material;
a first region of the first body with a first doping kind and a first doping concentration;
a second region of the first body with a second doping kind and a second doping concentration;
at least one junction formed between the first region and the second region;
a terminal arrangement connected to the first body and arranged to reverse bias the junction so as to emit light; and
a substrate, whereby the first body is formed integrally as part of the substrate and whereby the first body is formed from a deposited layer of semiconductor to form an integral part of the substrate.

48. The light emitting device of claim 47, in which the substrate is a plural material substrate.

49. The light emitting device of claim 47, in which the substrate is a single material substrate.

50. The light emitting device of claim 47, in which a crystal structure of the first body has characteristics within the continuum that spans from amorphous through polycrystalline up to, but not including, monocrystalline characteristics.

51. The light emitting device of claim 50, in which the crystal structure of the first body is polycrystalline or amorphous.

52. The light emitting device of claim 47, in which the first body is deposited on the substrate as part of the fabrication process used to produce integrated circuits.

53. The light emitting device of claim 47, in which the non-monocrystalline indirect band gap semiconductor material is a silicon material.

54. An integrated circuit which includes:
the light emitting device of claim 47; and
a second body of monocrystalline indirect band gap semiconductor material.

55. The integrated circuit of claim 54, in which the first and second bodies are separated by a third body which is configured to galvanically isolate the first and second bodies from each other.

56. The integrated circuit of claim 55, in which the first body is a polysilicon layer.

57. The integrated circuit of claim 55, in which the second and third bodies form part of the substrate.

58. The integrated circuit of claim 55, in which there are plural instances of the first body, formed from the non-monocrystalline material, distributed transversally over the monocrystalline second body.

59. The integrated circuit of claim 55, in which there are plural layers of the non-monocrystalline material which are vertically distributed and which form plural instances of the first body.

60. The integrated circuit of claim 59, in which the plural layers are deposited during fabrication of the integrated circuit, each of the plural layers separated by the third body which is an electrically non-conductive insulating layer.

61. The integrated circuit of claim 60, in which are least one of the plural layers is used to create passive circuit elements.

62. The integrated circuit of claim 55, in which the third body includes a plurality of layers comprised of a group of, but not limited to, inter-metal isolating layers, metal layers or other semiconducting materials.

63. The integrated circuit of claim 55, in which the third body includes at least one layer with an electrically non-conductive, or insulating, region between the first and second bodies.

64. The integrated circuit of claim 63, in which the third body comprises at least one of thermally grown SiO2, deposited SiO2, Si3N4, gas, vacuum or polymer layers.

65. The integrated circuit of claim 55, in which a photosensitive region is formed in the second body.

66. The integrated circuit of claim 65, in which the photosensitive region is configured to operate as a light detecting element positioned to capture light generated in the first body and traversing through the third body.

67. The integrated circuit of claim 55, which includes an auxiliary body, or plural auxiliary bodies, of a non-monocrystalline indirect band gap semiconductor material that is distinct from the first and second bodies.

68. The integrated circuit of claim 67, in which the auxiliary body is separated from the first and second bodies by the third body and in which the auxiliary body is deposited to form an integral part of the substrate.

69. The integrated circuit of claim 68, in which a photosensitive region is formed in the auxiliary body.

70. The integrated circuit of claim 55, in which the first body, excluding the terminal arrangement, is encapsulated by the third body.

71. The integrated circuit of claim 55, in which the first body is formed on top of the third body without being fully enclosed, thereby resulting in a partial bordering by the first body of the third body.

72. The integrated circuit of claim 65, which includes metal layers and in which the metal layers and the terminal arrangement are configured to reflect and direct the light generated in the first body towards the photosensitive region on the second body, or a photosensitive region on any other body, and to reduce optical propagation of light in a direction opposite the second, or additional, bodies comprising photosensitive regions.

73. The integrated circuit of claim 55, in which the first body is doped either using the same masks used to dope the underlying device layer, or a different set of masks targeting junction and feature formation specifically to address the configuration of a floating layer.

74. The integrated circuit of claim 55, in which the first body is electrically accessed using the same metal and by means of interconnect layers already available on chip as part of a fabrication process.

75. The integrated circuit of claim 74, in which the interconnect layers and corresponding interlayer dielectric are configured to control the propagation of light emitted from the light emitting device in order to make more efficient use of the emitted light.

76. The integrated circuit of claim 75, in which a reflective metal layer is provided underneath the light emitting device in order to reflect light towards the chip surface, thereby enabling more light to exit the chip surface.

77. An integrated circuit assembly comprising at least two integrated circuits of claim 65, which are co-located in a single package.

78. The integrated circuit assembly of claim 77, in which the integrated circuits are optical isolators.

79. The integrated circuit assembly as claimed in claim 78, in which a first integrated circuit containing a light emitting structure and a corresponding photosensitive detection region configured for optical communication between this region and the light source are positioned in proximity to a second integrated circuit.

80. The integrated circuit assembly of claim 78, in which the second integrated circuit provides a signal to control the light emitted from the light emitting structure on the first integrated circuit.

81. An integrated display including a plurality of light emitting devices of claim 47.

82. The integrated display of claim 81, in which the light emitting devices are arranged in an array or matrix where the light emitting structures can be individually addressed.

83. The integrated display of claim 82, in which an intensity of each individually addressable light emitting structure can be modulated.

84. A method of manufacturing an indirect band gap light emitting device, the method comprising:
depositing a layer of non-monocrystalline indirect band gap semiconductor material on a substrate to form an integral part of the substrate, the deposited layer forming a first body;
doping a first region of the first body with a first doping kind and a first doping concentration;
doping a second region of the first body with a second doping kind and a second doping concentration;
forming at least one junction between the first region and the second region; and
connecting a terminal arrangement to the first body, the terminal arrangement being arranged to reverse bias the junction so as to emit light.

85. A method of manufacturing an integrated circuit comprising the light emitting device manufactured by the method of claim 84, the method comprising providing a second body of monocrystalline indirect band gap semiconductor material and a third body of a non-conductive material, the third body galvanically isolating the first and second bodies from each other.

86. The method of claim 85, which includes forming a photosensitive region within the second body in order to optically couple and communicate between the first body and the second body through the third body.

87. A method of manufacturing an integrated circuit assembly comprising the integrated circuit manufactured by the method of claim 86, the method comprising co-locating at least two of the integrated circuits in a single package.

88. The method of claim 87, in which the integrated circuits are optical isolators and in which the method includes positioning a first integrated circuit containing a light emitting structure and a corresponding photosensitive detection region for optical communication between this region and the light emitting structure in proximity to a second integrated circuit.

89. The method of claim 88, in which the integrated circuits are bi-directional optical isolators.

90. The method of claim 88, which includes providing a signal by the second integrated circuit to control the light emitted from the light emitting structure on the first integrated circuit.

91. A method of communicating between the first and second integrated circuits of the integrated circuit assembly of claim 78, the method comprising:
emitting light by the light emitting structure of the first integrated circuit; and
receiving the emitted light by a photosensitive detection region of the second integrated circuit.

92. The method of claim 91, which includes providing a signal by the second integrated circuit to control the light emitted from the light emitting structure on the first integrated circuit.
